(19) United States
(12) Patent Application Publication
(10) Pub. No.: US 2004/0135241 A1
(43) Pub. Date: Jul. 15, 2004

(54) Secure transaction card with a large storage volume

(75) Inventors: Finis Conner, Pebble Beach, CA (US); Anil Nigam, Saratoga, CA (US); John Glavin, Pleasanton, CA (US); Jeng Ho, Saratoga, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: StorCard, Inc., Carmel, CA

(21) Appl. No.: 10/716,267

(22) Filed: Nov. 17, 2003

Related U.S. Application Data
(60) Provisional application No. 60/427,412, filed on Nov. 18, 2002.

(51) Int. Cl. H01L 23/02

(52) U.S. Cl. 257/679

(57) ABSTRACT

A portable electronic system configured for a secure transaction includes a card having a width, length, and thickness, wherein a ratio of length to thickness is at least 5. The card includes a storage medium to store data and an integrated circuit device (“IC”) including security information. The security information stored in the IC is used to authenticate an access request to the storage medium.

### CROSS-REFERENCES TO RELATED APPLICATIONS

The present application claims priority to U.S. Provisional Patent Application No. 60/427,412, filed on Nov. 18, 2002, which is incorporated by reference.

### BACKGROUND OF THE INVENTION

The present invention relates to a secure transaction card having a storage area.

Generally, users would like transactions, which could be an activity such as a financial exchange or the execution of a procedure to verify the identify of an individual or establishing a communication link between parties, to occur in a trusted environment and in the least amount of time. Currently, a number of platforms have been developed that provide a means to interact with other parties. In one configuration the communication occurs over a fixed network. The preferred requirement is for availability at anytime and anywhere but the unpredictability of network traffic limits the usability of such a system. Additionally, there are security concerns since confidential data may be transmitted over a public network; also civil liberty issues since personal information is communicated to a system which may be under the control of third parties.

Other methods utilize a card with electronics mounted on it. Such a card is referred to as a Smart Card. The Card carries the owner's credentials and provides a low level of authentication to complete a transaction. Smart Cards have about 16 kilobytes of data storage, which limits the level of security afforded by these cards. Smart Cards have the form factor of a credit card.

The Smart Cards integrated circuit is further constrained by the very small thickness of the Card and the requirement for a flexible structure. The electrical connection is via surface contacts with large pad areas creating a higher capacitance that limits the data transfer rate available from such a device. Despite these concerns, the Card is easily transportable and is very convenient to use.

### BRIEF SUMMARY OF THE INVENTION

In one embodiment, a portable electronic system configured for a secure transaction includes a card having a width, length, and thickness, wherein a ratio of length to thickness is at least 5. The card includes a storage medium to store data and an integrated circuit device (“IC”) including security information. The security information stored in the IC is used to authenticate an access request to the storage medium.

The portable electronic system also includes a reader to access the storage medium. The reader includes a first interface and a second interface. The first interface is configured to interface with the IC. The second interface is configured to interface with the storage medium. The ratio of the length to thickness of the card that is at least 8. Alternatively, the ratio of the length to thickness of the card is at least about 10.

### BRIEF DESCRIPTION OF THE DRAWINGS

FIG. 1 illustrates a secured transaction card according to one embodiment of the present invention.

FIG. 2 shows a card reader conforming to the PC Card form factor according to one embodiment of the present invention.

FIG. 3 shows a card with an integrated circuit and a rotating disk storage volume according to one embodiment of the present invention.

FIG. 4 illustrates certain internal details of the card of FIG. 3.

FIG. 5 shows certain internal details of a PC Card reader that works with the card shown in FIGS. 3 and 4.

FIG. 6 illustrates a block diagram of components in a secured transaction card according to one embodiment of the present invention.

FIG. 7 illustrates a block diagram of an integrated circuit mounted on the card shown in FIGS. 3 and 4 according to one embodiment of the present invention.

FIG. 8 shows an architecture of the electronics in the security module associated with a secured transaction card according to one embodiment of the present invention.

FIG. 9 shows a secured transaction card with Flash memory according to one embodiment of the present invention.

FIG. 10 is a side view of the card of FIG. 9.

FIG. 11 is a top view of the integrated circuit contact pads of the card of FIG. 9.

FIG. 12 depicts a structure of electronic components utilized in this Card.

FIG. 13 shows the electrical contacts for the Card with Flash memory.

FIG. 14 illustrates a block diagram of the architecture of the integrated circuit on the Card with Flash memory and the reader required to operate with this Card.

### DETAILED DESCRIPTION OF THE INVENTION

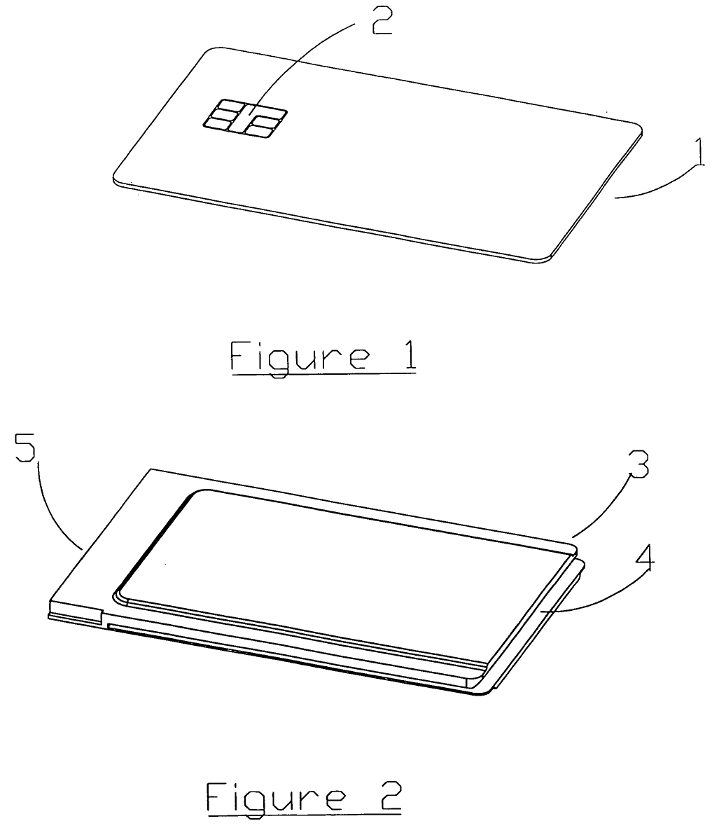

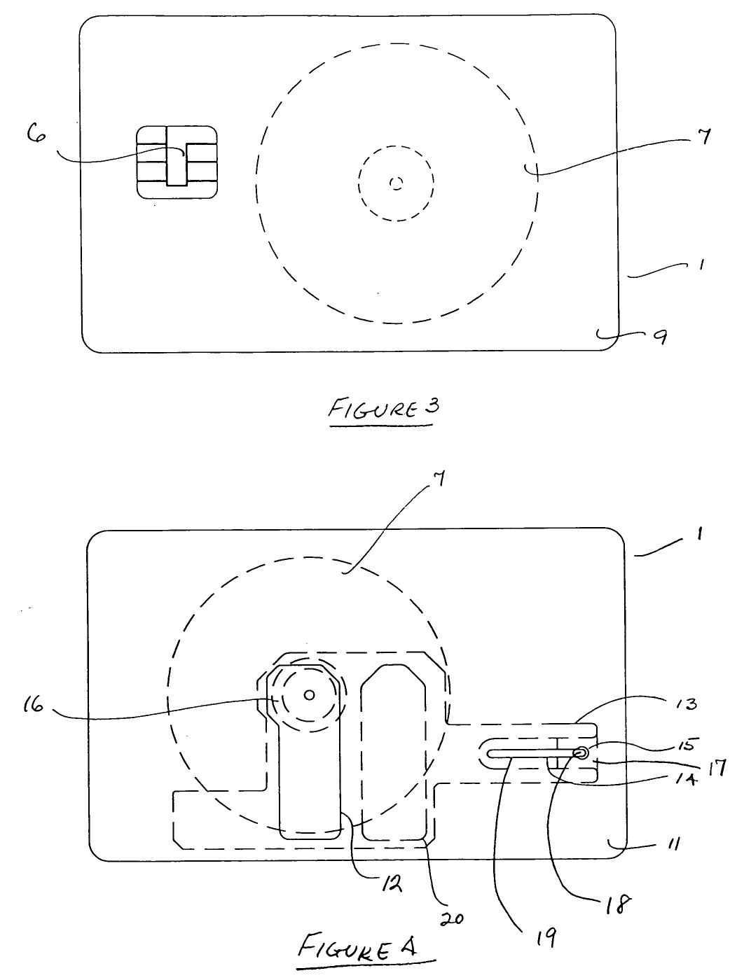

FIG. 1 illustrates a secured transaction card 1 as shown in FIG. 1. The card is configured similar to a Smart Card with an integrated circuit and surface contacts 2 and conforms to ISO 7816-1 and -2 specifications. Card 1 is inserted into a reader 3, such as that shown in FIG. 2. Card 1 is inserted into reader 3 through a slot 4 on one side of the reader, and it communicates with a host system through connector 5 on the opposite side.

In one embodiment, the card has a credit card form factor and conforms to the ISO 7816 specification. The ISO 7816 specification requires the card to have approximate dimensions of 3.37 inch by 2.125 inch by 0.03 inch. In other embodiments, the card may not have a credit card form factor. The dimensions of card may vary according to applications. The card may have a thickness anywhere in the range from 0.25 inch to 0.020 inch according to one embodiment of the present invention. In another embodiment, the card can be configured with a thickness in the range from about 0.020 inch to about 0.04 inch to allow the card to fit the sleeves in personal wallets. The card may also be provided with a length in the range from 0.5 inch to 4 inches. The width of the card may be in the range from 0.5 inch to 3.0 inches.

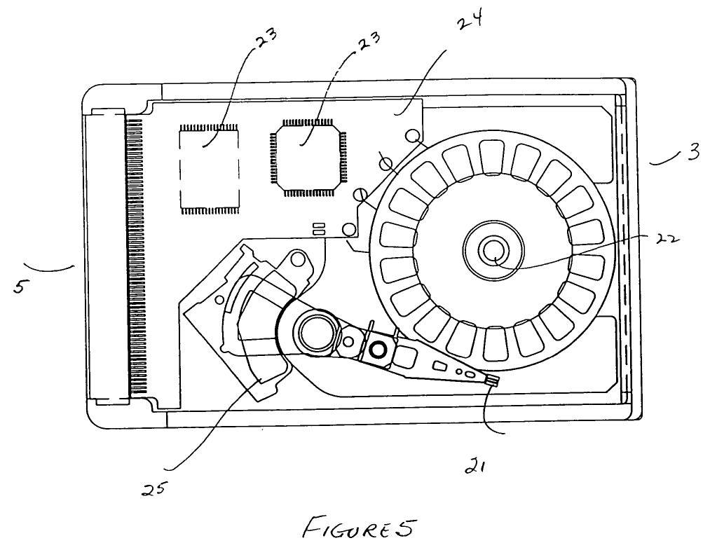

FIG. 3 shows one embodiment of card 1, which is constructed as a laminated structure. The card includes an integrated circuit with surface contacts 6 according to the ISO standard. Card 1 is thin and includes a flexible magnetic disk 7 housed in a cavity formed between the top cover 9, a core layer and the bottom cover 11 (FIG. 4). The disk thickness is about 0.0025 inch and the top cover 9 is about 0.006 inch, and the bottom cover 11 is made from a sheet of stainless steel about 0.003 inch thick. The core layer is about 0.018 inch thick. These layers are glued together forming card 1 with a thickness of about 0.030 inch. The cavity that contains disk 7 is about 0.015 inch in thickness. The surfaces of this cavity that face the disk are covered with a fabric liner (not shown). This liner protects disk 7 from contacting layers 9 and 11 of card 1.

FIG. 4 shows the bottom of card 1. There is an opening 12 in the bottom layer 11 behind which is located a shutter mechanism 13. This mechanism operates in a cavity formed in the core layer. The purpose of shutter 13 is to allow the recording surface of disk 7 to be exposed so that recording head 21 located in reader 3 can read and write information to the disk. Shutter 13 is made from 0.003 inch thick stainless steel sheet and reinforced by a 0.010 inch plastic member 17 attached at one end.

A pin, located in reader 3 (not shown), actuates the shutter through opening 15. The pin is located in slot 17 and upon continued insertion of card 1 into the reader the shutter is moved to position opening 20 in the shutter with opening 12 in plate 11. The pin in the reader moves in slot 19 fabricated in the bottom plate 11. Disk 7 is glued to a metal hub 16 and engages with spindle motor flange 22 mounted in reader 3, whereby the disk can be rotated at high speed to read and write data on disk 7. Upon removal of card 1 from reader 3, the pin moves shutter 13 to close the opening 12. The shutter gets locked in this position to eliminate casual actuation and protect contaminants from entering the disk enclosure.

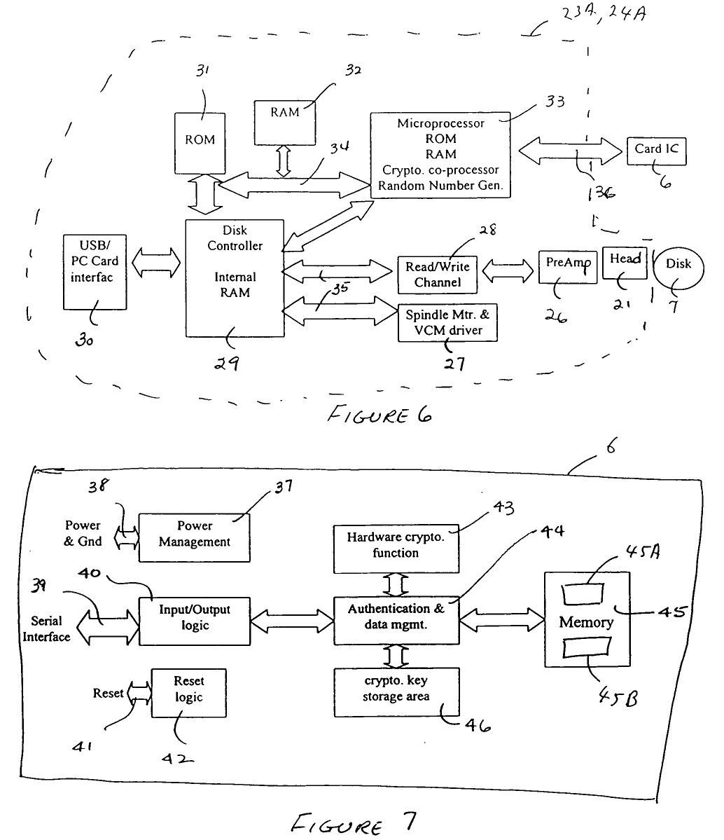

FIG. 5 illustrates a reader 3 according to one embodiment of the present invention. Reader 3 is constructed as a Type II PC Card being 0.197 inch thick. It can be inserted into slots available in portable computers, where communication can be established between the host system and reader 3 through a connector 5. Spindle motor 22 in the reader centers the disk 7 and hub 16 assembly such that the center of the data track is within a prescribed tolerance of the rotational center of the spindle. Recording head 21 is loaded against disk 7 during operation with a vertical force of about 3 grams. Upon high-speed rotation of disk 7, head 21 establishes a non-contact interface, whereby information can be recorded to and read from the tracks on disk 7 at high data transfer rates. In one implementation, the data transfer rate is greater than 5 megabytes per second.

In addition, head 21 can be moved rapidly from track to track on the disk by a Voice-Coil Motor arrangement 25. The average accessing performance of such a mechanism is less than 0.015 milli-second. Reader 3 contains a printed circuit board 24, on which are mounted integrated circuits 23 to control the reader mechanism and supervise the flow of data between disk 7, the integrated circuit 6 and the host system.

FIG. 6 shows a block diagram of the electronic architecture of a reader and a card according to one embodiment of the present invention. The components included in the reader is provided inside a line 23A, and 24A. The remaining components are included in the card.

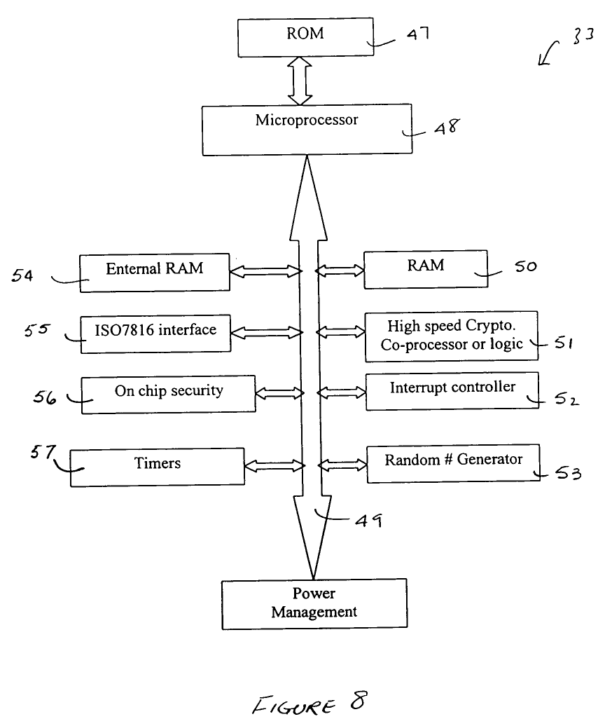

The card integrated circuit (IC) 6 is connected via a secure bus 36 to a security module 33. This module has a ROM and RAM, a cryptography co-processor in one embodiment running a 3DES or AES encryption algorithm. Module 33 also have a Random number generator. Bus 36 and module 33 are potted with secure epoxy. Data contained on disk 7 is communicated through a separate path and is read by head 21 located in reader 3. The head generates a signal each time it passes a magnetic transition. These signals are amplified by circuits contained in pre-amplifier 26 and transmitted to the read/write channel 28. The data is separated and an NRZ serial stream is sent to the disk controller 29. The controller 29 contains ECC logic to correct data errors and a sequencer to separate the data into blocks and write it to an internal RAM. The disk controller also controls the spindle motor speed and the position of head 21. The servo loop algorithms operating in controller 29 are interrupt driven, and control the position of the head accurately to follow the centerline of each data track, and to seek the head to other tracks on disk 7. The data recorded on disk 7 is encrypted and memory 45 (FIG. 7) on the card contains the encryption keys.

FIG. 7 illustrates internal functions performed by the card IC 6 according to one embodiment. This is a secure memory device and contains no microprocessor in the present implementation. It can communicate over a serial bus 39 with the Input/Output logic, which in one embodiment conforms to ISO 7816-3 and can operate at a maximum speed of 115 kilo-baud. Power management block 37 and reset logic 42 control the power and security features to keep the memory on the device protected from unauthorized attacks.

A hardware crypto-function 43 operates in concert with the memory management block 44. These elements authenticate requests prior to providing access to the session keys stored in memory 45. Card serial number and enrollment keys are stored in a secure memory area 46. Memory 45 is partitioned into secure and un-secure zones 45A and 45B to allow card 1 to operate as a Smart memory card or as a secure high capacity storage device.

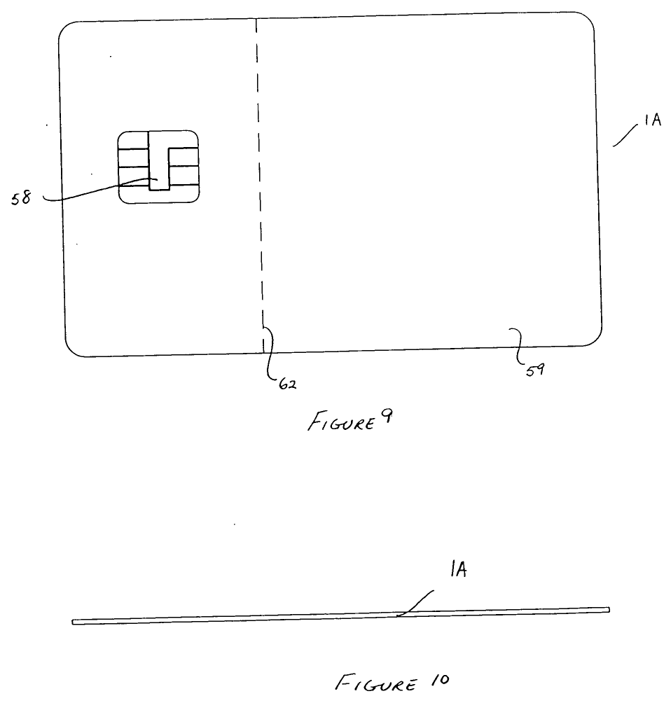

FIG. 8 illustrates an internal architecture of module 33 according to one embodiment of the present invention. The microprocessor unit 48 could be a 16 bit or 32 bit RISC processor with an operating system contained in ROM 47. RAM 50 is accessed on bus 49 which could be an 8 bit or 16 bit bus. Microprocessor instructions can be executed from RAM or ROM. Programs stored in disk 7 can be loaded into RAM 50 and executed. A high-speed cryptography processor 51 with a throughput of greater than 5 megabytes per second, an interrupt controller 52, and a FIPS 140 compliant Random number generator are also accessible on bus 49. The module also includes timers 57, security logic 56, and an ISO 7816 interface 55 to communicate with card IC 6.

Referring back to FIGS. 6 and 7, interface 36 coupling module 33 and card IC 6 includes three interfaces 38, 39 and 41. These three interfaces are potted in reader 3 to keep module 33 secure and tamper-proof. Furthermore, disk controller 29, read/write channel 28, pre-amp 26 and spindle motor/VCM driver 27 are circuits that are commonly used in most hard disk drive products. The program code to operate the servo system and the data sequencer is stored in ROM 31. Data is communicated to the host through interface 30 which could either be PC Card or USB. The disk controller can access RAM 32. Also microprocessor 48 can read and write to this RAM. In one embodiment data exchange between Controller 29 and secure module 33 is through RAM 32.

Disk controller 29 can be emulated and all information in internal RAM and RAM 32 is accessible through interface 30 or through other ports on controller 29. Microprocessor 48 communicates with the disk controller 29 via interrupts and RAM 32. Accordingly, all elements in module 33 are secure and immune from attacks. The physical device is potted with secure epoxy along with the connections represented by interface 36 such that any attempts to probe these circuits would require removal of the epoxy and destruction of the device and the respective cables.

Data written to disk 7 can be encrypted with the session keys stored in memory 45 contained on card IC 6. As a disk drive the control electronics contains cipher text in the disk controller 29, internal RAM and external RAM 32. The encryption keys are communicated between module 33 and the card IC 6 over the secure bus 36. This architecture can be configured to operate in a variety of ways. As an authentication mechanism, card 1 includes encrypted biometric information of the owner with the encryption keys securely loaded in memory 45. This is done during enrollment of the user. The card is also provided with a serial number.

In one embodiment, the procedure of installing the security wall in card 1 includes the serial number and a random number being encrypted together using a two key asymmetric algorithm. A private key would encrypt this information creating a cipher text. This text is stored in block 46.

When the card is inserted into a reader 3, microprocessor 48 would issue a challenge to the card. The card would respond by transmitting this cipher text. Microprocessor 48 decrypts the text using the public key stored in ROM 47 and creates a cipher-gram using a random number from module 53 and a symmetric encryption algorithm similar to that implemented in hardware block 43. This cipher-gram is sent to card 1, where it is processed by module 43. If the results match, the card authenticates the reader. Furthermore, since microprocessor decrypted the initial cipher text successfully the reader is also authenticated.

At this point microprocessor 48 has access to memory 45 containing the encryption keys and information about disk 7. Communication over bus 36 is limited to 115 kilo-baud. The challenge response may be executed continuously at this slow speed to ensure continued authenticity of this engagement. Other algorithms may be utilized to achieve the required level of authentication.

The host has installed in it a biometric sensor or a pin number entry system by which the card owner would request authentication. In one embodiment, the biometric data is transmitted to reader 3 with a request to verify authenticity. This data may reside in internal RAM of the controller or get written to a scratch file on disk 7. The disk controller transfers control to microprocessor 48.

A request for the file containing the encrypted biometric template is issued by microprocessor 48 to controller 29. The cipher text is fetched from the disk and written to RAM 32 or transmitted serially to module 33. This information is decrypted and compared with the data written in the scratch disk. A match or a reject result is then communicated from microprocessor 48 to the host via controller 29 and interface 30.

Other sequence of events may also be utilized to create a trusted environment where the card and reader authenticate themselves, cipher text is all that can be viewed in the non-secure modules while the decrypted information and file matching is done in the secure module 33. Many session keys and random numbers may be utilized to achieve the required security.

This architecture of the card provides a low cost secure memory circuit and a flexible magnetic disk that cost less than $2.00. The reader has the secure micro-controller 33 and logic, which is amortized over a large number of cards to create a secure, low cost access control system. Data rates from the disk may be 5 to 50 megabytes per second in one implementation, while the reader being a larger structure can have circuits in module 33 running at speeds of about 100 to 400 Megabits per second. This provides rapid transactional speed and reduces wait, e.g., reduces the waiting lines at airport security check points, border entry points and secure access to facilities, buildings and transportation systems.

In another embodiment, disk 7 stores fully encrypted applications with data also encrypted and stored in another file on the same disk. The host requests information, which requires the application and data to be downloaded to module 33 decrypted, executed and the results communicated to the host. This architecture ensures that secure information remains in the card and the reader and only the results are transmitted to the host, whereby a firewall is created between the host and the data on the disk 7. The encryption keys are stored behind another firewall created in the card integrated circuit during enrollment of the user.

FIG. 9 illustrates a card 1A according to another embodiment of the present invention. Card 1A is a laminated structure with an integrated circuit module 58 that has multiple devices. Card 1A conforms to ISO 7816 for flexibility and has the same thickness as a credit card as shown in FIG. 10 in the present embodiment. The card includes a flexible circuit 62, a plastic housing 59. FIG. 10 illustrates an enlarged view of the circuit module.

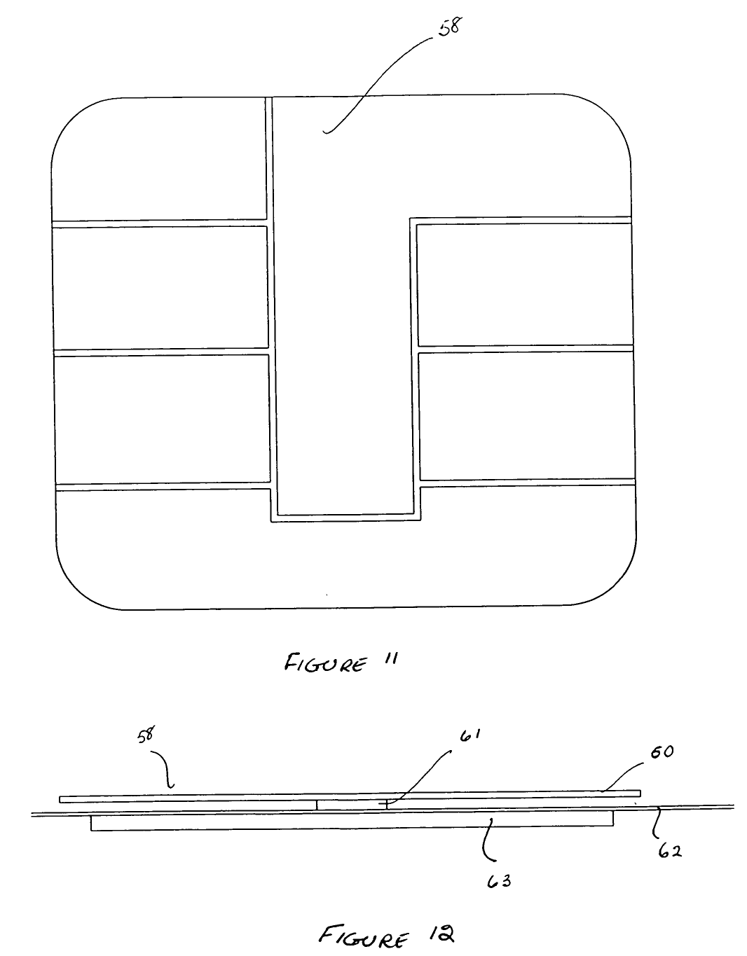

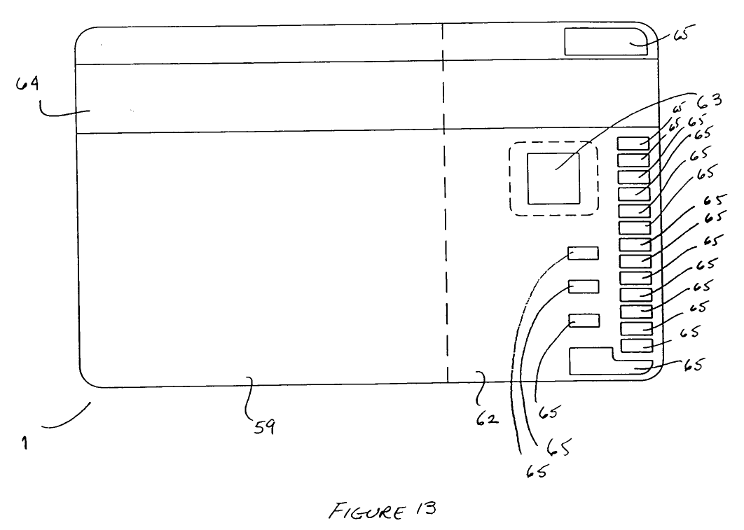

FIG. 12 illustrates a cross-sectional view of the card according to one embodiment of the present invention. Surface contacts of module 58 are attached to a circuit block or IC die 61. In one embodiment, the circuit block is formed on a single semiconductor die and includes the functional blocks illustrated in FIG. 7. A flexible circuit 62 is provided below the IC die 61. A flash memory 63 is provided below the flexible circuit, i.e., the die and the flash memory are provided on the opposite surfaces of the flexible circuit. The flash memory is used as a storage device in the present embodiment and corresponds to disk 7 in FIG. 6.

The flash memory die has the dimensions such that it is contained in the area identified for the circuit elements on the card. In the present embodiment, IC die 61 is provided directly over the flash memory. In another embodiment, the circuit module or IC die 61 and flash memory 63 are integrated in a single semiconductor device. In yet another embodiment, the circuit module 61 is spaced apart from the flash memory.

In the present embodiment, the thickness of the IC die 61 is about 160 microns and the flash memory die is about 210 microns thick. The flexible circuit cable is about 0.002 inch thick. Contact pads are about 0.005 inch thick. The resulting structure has a thickness of about 0.024 inch. This structure is mounted into card 1A such that it is about 0.006 inch thick to keep the card compliant with ISO specifications.

The benefit of such a construction is that the electronics are in the same position as in a Smart Card to achieve similar handling characteristics, and the cost of circuit module 61 is not burdened with expensive processing required to fabricate embedded flash memory. Furthermore, this configuration allows two high volume devices to be integrated into a card to provide low manufacturing cost.

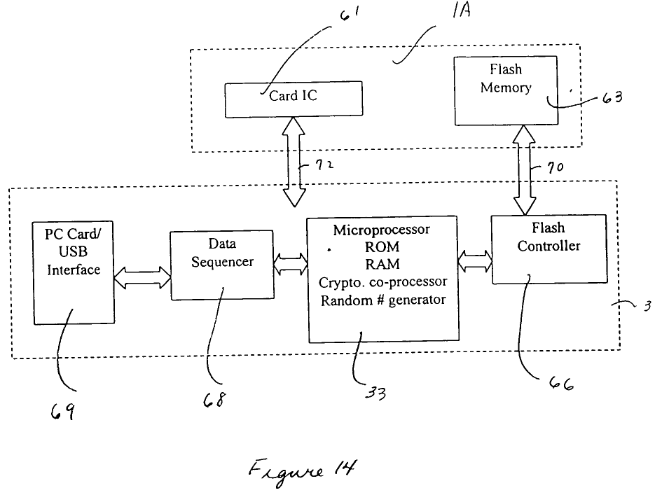

FIG. 13 shows a bottom view of card 1A according to one embodiment of the present invention. A plurality of contact pads 65 are provided on the back side of the card. A magnetic stripe 64 is also constructed on the back of the card to provide compatibility with legacy systems. Card 1A requires a reader with a connector to access contacts 65 and the low speed surface contacts 58.

FIG. 14 illustrates an electronics architecture of card 1A according to one embodiment of the present invention. The card has a card IC 61 and a flash memory 63. A reader 3 is used to access the card. The reader has a flash controller 66, a security module 33, a data sequencer 68, and an interface 69.

In the present embodiment, the flash memory and the card IC are accessed by the reader using separate communication paths 70 and 72. The flash memory is accessed using contacts 65, i.e., communication path 70. Flash controller 66 provided in the reader manages the read and write operations to the flash memory. The security module 33 is similar to the one described for the rotating magnetic disk embodiment in FIG. 6. The IC 61 is accessed using surface contacts 58 on the front side of the card, i.e., communication path 72 that is coupled to security module 33. One benefit of using flash memory is that it requires less footprint than the magnetic disk and is price competitive with the magnetic disk for those devices requiring low storage capacities. If the device requires a large storage capacity, the magnetic disk generally is a more economical solution.

The present invention has been described in terms of specific embodiments. Modifications, alterations, or changes may be made to the illustrated embodiments without departing from the scope of the present invention. Accordingly, the scope of the present invention should be interpreted using the appended claims.

What is claimed is:

1. A portable electronic system configured for a secure transaction, comprising:
a card having a width, length, and thickness, wherein a ratio of length to thickness is at least 5;
a storage medium to store data; and
an integrated circuit device (“IC”) including security information,
wherein the storage medium and the IC are provided within the card and;
wherein the security information stored in the IC is used to authenticate an access request to the storage medium.

2. The portable electronic system of claim 1, further comprising:
a reader to access the storage medium, the reader including a first interface and a second interface, the first interface being configured to interface with the IC and the second interface being configured to interface with the storage medium.

3. The portable electronic system of claim 2, wherein the reader further includes:
a security module coupled to the first interface and including a first processor, the security module cooperating with the IC to authenticate the access request.

4. The system of claim 3, wherein the security module further includes:
a read-only memory, and
a second processor configured to perform encryption or decryption algorithm.

5. The system of claim 4, wherein the security module further includes:
a random number generator, and
a random access memory.

6. The system of claim 1, wherein the storage medium is a non-volatile semiconductor device.

7. The system of claim 1, wherein the storage medium is a flash memory.

8. The system of claim 7, wherein the IC is provided directly over the flash memory.

9. The system of claim 8, wherein an circuit interface is provided between the IC and the flash memory.

10. The system of claim 9, wherein the circuit interface is a flexible circuit.

11. The system of claim 1, wherein the IC includes a memory, a security information storage area for storing the security information, and a cryptography module.

12. The system of claim 11, wherein the security information is a cryptography key.

13. The system of claim 12, wherein the memory includes a secured area and a non-secured area.

14. The system of claim 1, wherein the storage medium on the card is a disk, the card including a pin that is configured to move along a first direction and a second direction.

15. The system of claim 14, wherein the pin moves along the first direction if the card is inserted into a reader to provide an opening for accessing the disk.

16. The system of claim 15, wherein the pin moves along the second direction if the card is removed from the reader, thereby closing the opening.

17. The system of claim 1, wherein the ratio of the length to thickness is at least 8.

18. The system of claim 1, wherein the ratio of the length to thickness is at least about 10.
